(19) United States
(12) Patent Application Publication
(10) Pub. No.: US 2025/0089206 A1
(43) Pub. Date: Mar. 13, 2025

(54) IMMERSION COOLING APPARATUS

(71) Applicants: SAMSUNG C&T CORPORATION, Seoul (KR); DATABEAN CO., LTD., Suwon-Si (KR)

(72) Inventors: Eun Young Jung, Suwon-Si (KR); Hoon Chae Park, Daejeon (KR); Ho Suk Kang, Seoul (KR); Ju Hyung Lee, Suwon-si (KR); Joon Ho Park, Anyang-si (KR); Eui Sun Jin, Hanam-si (KR); Jun Hyeok Yoo, Yongin-si (KR); Soo Yong Kim, Yongin-si (KR)

(73) Assignees: SAMSUNG C&T CORPORATION, Seoul (KR); DATABEAN CO., LTD., Suwon-Si (KR)

(21) Appl. No.: 18/725,066

(22) PCT Filed: Dec. 5, 2023
(86) PCT No.: PCT/KR2023/019925

§ 371 Date: Jun. 27, 2024

(30) Foreign Application Priority Data
Dec. 7, 2022 (KR) 10-2022-0169453

(51) Int. Cl. H05K 7/20

(52) U.S. Cl. CPC H05K 7/20272; H05K 7/20236; H05K 7/20772

(57) ABSTRACT

The present invention relates to an immersion cooling apparatus including a chamber, a rack module installed in the chamber and having a plurality of slots each having a cooling target mounted thereon, a supply part connected to the chamber and configured to supply a cooling fluid to the inside of the chamber, and a discharge part disposed to be spaced apart from the supply part and configured to discharge the cooling fluid from the chamber.

### TECHNICAL FIELD

The present invention relates to an immersion cooling apparatus, and more particularly, to an immersion cooling apparatus that allows a cooling fluid to efficiently flow inside an immersion tank.

### BACKGROUND ART

Generally, data centers lease computational equipment or network equipment to a business or an individual or takes a client's equipment and provides services such as maintenance and repair. Usually, in server rooms of such data centers, multiple rows of racks on which data servers, which include communication devices, and databases are mounted are installed, and a workspace where a worker can work is included.

A cooling system for cooling a large amount of heat generated from a central processing unit (CPU) or a graphics processing unit (GPU) of servers is essentially required in such data centers. Conventionally, servers are cooled by an air cooling method using an air blowing device such as a cooling fan or a blower, but such an air cooling method has problems in that an excessive installation space is occupied, and energy consumption is high.

The related art of the present invention is disclosed in Korean Unexamined Patent Application Publication No. 10-2016-0128285 (Date of Publication: Nov. 7, 2016, Title of Invention: Apparatus for cooling sever room and air conditioning system for data center therewith).

### DISCLOSURE

### Technical Problem

The present invention is directed to providing an immersion cooling apparatus that allows a cooling fluid to efficiently flow inside an immersion tank.

### Technical Solution

The present invention provides an immersion cooling apparatus including: a chamber; a rack module installed in the chamber and having a plurality of slots each having a cooling target mounted thereon; a supply part connected to the chamber and configured to supply a cooling fluid to the inside of the chamber; and a discharge part disposed to be spaced apart from the supply part and configured to discharge the cooling fluid from the chamber.

The slot may have both sides passing through the rack module to communicate with an inner space of the chamber, and the supply part and the discharge part may be disposed to be spaced apart from each other in an extending direction of the slot for the cooling fluid to flow through the slot.

The supply part may be disposed at a lower side of the chamber, and the discharge part may be disposed at an upper side of the chamber.

The supply part may include: a supply body fixed to the inside of the chamber; a supply flow path portion extending from the supply body and disposed to face one side of the slot; and a supply hole portion formed to pass through the supply flow path portion and configured to spray the cooling fluid toward the one side of the slot, and the discharge part may include: a discharge body fixed to the inside of the chamber and disposed to be spaced apart from the supply body; a discharge flow path portion extending from the discharge body; and a first discharge hole formed to pass through one surface of the discharge flow path portion and configured to suction the cooling fluid discharged from the other side of the slot.

The plurality of slots may be arranged in at least two or more rows in a first direction, and the supply flow path portion and the discharge flow path portion may extend in a direction parallel to the first direction.

The supply hole portion may include a plurality of supply holes, and each of the slots may be disposed to face at least one or more of the supply holes.

The plurality of supply holes may be arranged in at least two or more rows in the first direction.

The plurality of supply holes may have diameters that increase proportionally to a distance from the first discharge hole.

Among the plurality of supply holes, the supply hole whose distance from the first discharge hole is smaller than a first predetermined distance may have a first diameter, and the supply hole whose distance from the first discharge hole is larger than the first predetermined distance may have a second diameter.

The plurality of slots may be arranged in at least two or more rows in a second direction perpendicular to the first direction, and the plurality of supply holes may be arranged in at least two or more rows in the second direction.

The plurality of slots may be arranged in at least two or more rows in a second direction perpendicular to the first direction, and the supply flow path portion may be provided as a plurality of supply flow path portions that are arranged in at least two or more rows in the second direction.

Each of the supply flow path portions may be disposed to face a different row of the slots arranged in the second direction.

The first discharge hole may be provided as a plurality of first discharge holes, and the plurality of first discharge holes may be arranged in at least two or more rows in the first direction.

Each of the first discharge holes arranged in the first direction may be disposed to face a different row of the slots arranged in the first direction.

The plurality of first discharge holes may have diameters that increase proportionally to a distance from the discharge body.

The discharge part may further include a second discharge hole formed to pass through the other surface of the discharge flow path portion and configured to prevent bubbles from being introduced into the discharge flow path portion.

The first discharge hole may be formed to pass through a side surface of the discharge flow path portion, and the second discharge hole may be formed to pass through a lower surface of the discharge flow path portion.

The discharge part may further include a third discharge hole configured to prevent the cooling fluid from stagnating in the chamber.

The first discharge hole and the third discharge hole may be disposed at both ends of the discharge flow path portion.

### Advantageous Effects

In an immersion cooling apparatus according to the present invention, by a supply part and a discharge part allowing a cooling fluid to continuously flow in a chamber, a decrease in cooling efficiency due to stagnation of the cooling fluid can be prevented.

In an immersion cooling apparatus according to the present invention, by a plurality of supply holes directly spraying a cooling fluid into each slot, a flow speed of the cooling fluid passing through each slot can be increased, and efficiency of cooling a cooling target can be further improved.

In an immersion cooling apparatus according to the present invention, since a plurality of supply holes are each formed to have a diameter that increases proportionally to a distance from a first discharge hole, a plurality of cooling targets can be uniformly cooled regardless of the positions of slots.

In an immersion cooling apparatus according to the present invention, by a second discharge hole configured to suction a cooling fluid at a different position from a first discharge hole, a phenomenon of a local decrease in the level of the cooling fluid in a region adjacent to the first discharge hole can be mitigated in some parts, and introduction of bubbles into a discharge flow path portion can be prevented.

In an immersion cooling apparatus according to the present invention, by a third discharge hole suctioning a cooling fluid located in a dead water zone toward a discharge flow path portion, a phenomenon of stagnation of the cooling fluid in a chamber can be relieved.

In an immersion cooling apparatus according to the present invention, by a plurality of supply holes and first discharge holes forming separate flow paths for each slot, uniform cooling performance can be secured for a plurality of slots.

In an immersion cooling apparatus according to the present invention, since a plurality of first discharge holes are formed to have a diameter that increases proportionally to a distance from a discharge body, a flow rate of a cooling fluid introduced into each first discharge hole can be uniformly maintained.

### DESCRIPTION OF DRAWINGS

The following drawings attached to the present specification illustrate exemplary embodiments of the present invention and serve to further facilitate understanding of the technical spirit of the present invention together with the detailed description of the invention given below, and thus the present invention should not be interpreted as being limited to the details shown in the drawings.

FIG. 1 is a perspective view schematically illustrating a configuration of an immersion cooling apparatus according to one embodiment of the present invention.

FIG. 2 is a perspective view schematically illustrating the configuration of the immersion cooling apparatus excluding a rack module according to one embodiment of the present invention.

FIG. 3 is a perspective view schematically illustrating a configuration of a supply part according to one embodiment of the present invention.

FIG. 4 is a plan view schematically illustrating the configuration of the supply part according to one embodiment of the present invention.

FIG. 5 is a perspective view schematically illustrating a configuration of a discharge part according to one embodiment of the present invention.

FIG. 6 is a view schematically illustrating a correlation between a diameter of a plurality of supply holes and a first discharge hole according to one embodiment of the present invention.

FIG. 7 is a view schematically illustrating operational states of the supply hole and the first discharge hole according to one embodiment of the present invention.

FIG. 8 is an enlarged view schematically illustrating a configuration of a second discharge hole according to one embodiment of the present invention.

FIG. 9 is a view schematically illustrating an operational state of the second discharge hole according to one embodiment of the present invention.

FIG. 10 is a view schematically illustrating an operational state of a third discharge hole according to one embodiment of the present invention.

FIG. 11 is a view schematically illustrating an experimental result of the immersion cooling apparatus according to one embodiment of the present invention.

FIG. 12 is a perspective view schematically illustrating a configuration of an immersion cooling apparatus according to another embodiment of the present invention.

FIG. 13 is a perspective view schematically illustrating the configuration of the immersion cooling apparatus excluding a rack module according to another embodiment of the present invention.

FIG. 14 is a perspective view schematically illustrating a configuration of a supply part according to another embodiment of the present invention.

FIG. 15 is a perspective view schematically illustrating a configuration of a discharge part according to another embodiment of the present invention.

FIG. 16 is a view schematically illustrating a correlation between diameters of a plurality of first discharge holes according to another embodiment of the present invention.

### MODES OF THE INVENTION

Hereinafter, exemplary embodiments of the present invention will be described in detail with reference to the accompanying drawings. Prior to the description, it should be noted that terms or words used in the specification and the claims should not be interpreted as being limited to their general or dictionary meanings and should be interpreted to have meanings and concepts consistent with the technical spirit of the present invention, according to the principle that the inventor may appropriately define concepts of terms in order to describe his or her invention in the best possible way. Therefore, the embodiments described in the specification and the configurations illustrated in the drawings are only some exemplary embodiments of the present invention and do not represent the entire technical spirit of the present invention, and thus it should be understood that various equivalents and modifications that can replace the embodiments may be present at the time of filing this application.

Also, terms such as “comprise/include” and/or “comprising/including” used herein specify the presence of mentioned shapes, numbers, steps, operations, members, components, and/or groups thereof and do not preclude the presence or addition of one or more other shapes, numbers, steps, operations, members, components, and/or groups thereof.

Also, to help understanding of the invention, dimensions of some components may be exaggerated instead of being drawn to scale in the accompanying drawings. Also, the same components may be denoted by the same reference numerals in different embodiments.

When two comparison objects are mentioned as being “the same,” it means that they are “substantially the same.” Being substantially the same may include a case of having a variation that is considered low in the art, for example, a variation within 5%. Also, when a certain parameter is described as being uniform in a predetermined region, this may mean that the parameter is uniform in an average perspective.

Although terms such as first and second are used to describe various components, of course, the components are not limited by the terms. The terms are only used to distinguish one component from another component, and of course, a first component may also be a second component unless particularly stated otherwise.

Throughout the specification, each component may be singular or plural unless particularly stated otherwise.

When an arbitrary configuration is described as being disposed “above (or beneath)” a component or “on (or under)” a component, this may not only mean that the arbitrary configuration is disposed in contact with an upper surface (or lower surface) of the component but also mean that another configuration may be interposed between the component and the arbitrary configuration disposed on (or under) the component.

Also, when a certain component is described as being “on.” “connected to,” or “coupled to” another component, it should be understood that, although the components may be directly connected or linked to each other, another component may be “interposed” between the two components, or the two components may be “connected.” “coupled,” or “linked” to each other through another component.

As used in the present specification, the term “and/or” includes any and all combinations of one or more of associated listed items. Also, when describing the embodiments of the present disclosure, the use of “may” relates to “one or more embodiments of the present disclosure.” Expressions such as “one or more,” when preceding a list of components, modify the entire list of components and do not modify the individual components of the list.

Throughout the specification, “A and/or B” means A, B, or A and B unless particularly stated otherwise, and “C to D” means larger than or equal to C and smaller than or equal to D unless particularly stated otherwise.

When a phrase such as “at least one of A, B, and C,” “at least one of A, B, or C,” “at least one selected from the group consisting of A, B, and C,” or “at least one selected from A, B, and C” is used in designating a list of components A, B, and C, the phrase may indicate any and all suitable combinations.

The term “use” may be considered as a synonym of the term “utilize.” As used in the present specification, the terms “substantially” and “about” and other similar terms are used as approximate terms instead of exact terms to consider intrinsic volatility of measured or calculated values to be recognized by those of ordinary skill in the art.

In the present specification, terms such as first, second, and third may be used to describe various elements, components, regions, layers, and/or sections, but the elements, components, regions, layers, and/or sections should not be limited by the terms. The terms are used to distinguish one element, component, region, layer, or section from another element, component, region, layer, or section. Therefore, a first element, a first component, a first region, a first layer, or a first section discussed below may be referred to as a second element, a second component, a second region, a second layer, or a second section without departing from the teachings of the exemplary embodiments.

Spatially relative terms such as “beneath,” “below,” “lower,” “above,” and “upper” may be used in the present specification for ease of description in order to describe the relationship between one component or feature and another component(s) or feature(s). Spatially relative positions should be understood as encompassing different directions of a device that is in use or operating, in addition to directions depicted in the drawings. For example, when an apparatus in a drawing is flipped, a component described as being “below” or “beneath” another component is understood as being “on” or “above” the other component. Therefore, the term “below” may encompass both upward and downward directions.

The terms used in the present specification are for describing the embodiments of the present disclosure and are not intended to limit the present disclosure.

Hereinafter, in describing the present invention using several embodiments, repeated description of identical or corresponding components throughout several embodiments will be omitted. For example, when a configuration that is identical or corresponds to a configuration disclosed in one embodiment is disclosed in another embodiment, the description of the corresponding configuration will be omitted in description of another embodiment, and a configuration that has a difference from one embodiment will be mainly described.

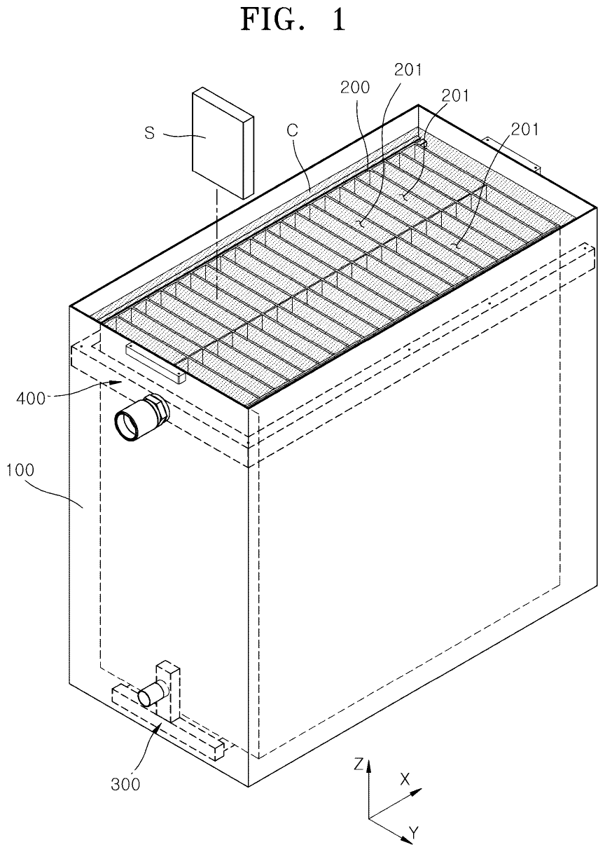

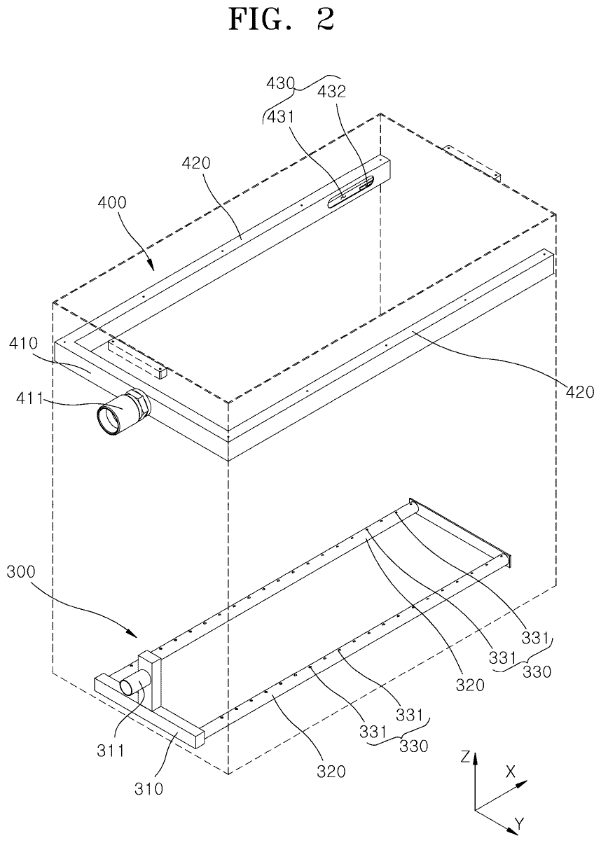

FIG. 1 is a perspective view schematically illustrating a configuration of an immersion cooling apparatus according to one embodiment of the present invention, and FIG. 2 is a perspective view schematically illustrating the configuration of the immersion cooling apparatus excluding a rack module according to one embodiment of the present invention.

Referring to FIGS. 1 and 2, an immersion cooling apparatus according to one embodiment of the present invention includes a chamber 100, a rack module 200, a supply part 300, and a discharge part 400.

The chamber 100 forms an overall exterior of the immersion cooling apparatus and supports the rack module 200, the supply part 300, and the discharge part 400, which will be described below, as a whole. For example, the chamber 100 may be formed to have the shape of a rectangular parallelepiped box that is hollow. A cooling fluid C may be accommodated in the chamber 100. The cooling fluid C may be a nonconductive liquid material including a synthetic oil such as synthetic poly alpha olefins (PAOs), synthetic gas to liquids (GTLs), and synthetic esters.

The rack module 200 is installed in the chamber 100 and immersed in the cooling fluid C accommodated in the chamber 100. For example, the rack module 200 may be formed to have the shape of a substantially rectangular parallelepiped box. The volume of the rack module 200 may be formed smaller than the volume of the chamber 100. The rack module 200 may be supported inside the chamber 100 by a separate bracket or the like while immersed in the cooling fluid C. A lower surface of the rack module 200 may be disposed to be spaced a predetermined distance apart from a bottom surface of the chamber 100. An upper surface of the rack module 200 may be disposed at a position lower than the level of the cooling fluid C accommodated in the chamber 100.

A slot 201 on which a cooling target S is mounted may be formed in the rack module 200. Here, the cooling target S may include at least any one or more of various types of heating elements to be cooled such as a server, a storage, a network switch, a central processing unit (CPU), and a battery module of an energy storage system (ESS).

The slot 201 may be formed as a plurality of slots 201. A plurality of cooling targets S may be individually mounted on the plurality of slots 201. The cooling targets S may be detachably mounted on the slots 201 by bolting, fitting, and the like.

The slot 201 may be formed to have the shape of a hole that is formed to pass through the rack module 200. The slot 201 may have a longitudinal direction that extends in a direction parallel to an up-down direction, that is, the Z-axis direction (based on FIGS. 1 and 2). Both sides of the slot 201 may pass through the upper surface and the lower surface of the rack module 200 and communicate with an inner space of the chamber 100. Accordingly, the cooling fluid C accommodated in the chamber 100 may be introduced into the slot 201 and further improve efficiency of cooling the cooling target S mounted on the slot 201.

The plurality of slots 201 may be disposed parallel to each other in the rack module 200. The plurality of slots 201 may be arranged in a lattice shape in the rack module 200. Neighboring slots 201 may be partitioned from each other by a partition or the like.

The plurality of slots 201 may be arranged in at least two or more rows in a first direction in the rack module 200. Here, the first direction may be a direction parallel to the X-axis direction based on FIGS. 1 and 2. For example, as illustrated in FIG. 1, the plurality of slots 201 may be arranged in twenty one rows in the first direction.

The plurality of slots 201 may be arranged in at least two or more rows in a second direction perpendicular to the first direction. Here, the second direction may be a direction parallel to the Y-axis direction based on FIGS. 1 and 2. For example, as illustrated in FIG. 1, the plurality of slots 201 may be arranged in two rows in the second direction.

The supply part 300 and the discharge part 400 are connected to the chamber 100 and circulate the cooling fluid C accommodated in the chamber 100. The supply part 300 supplies the cooling fluid C to the inside of the chamber 100, and the discharge part 400 discharges the cooling fluid C from the chamber 100. In this way, the cooling fluid C may flow through the slot 201.

The supply part 300 and the discharge part 400 may be connected to a pump (not illustrated) separately installed outside the chamber 100 and may receive a driving force for a flow of the cooling fluid C from the pump. Accordingly, the supply part 300 and the discharge part 400 may allow the cooling fluid C to continuously flow in the chamber 100 and further improve the efficiency of cooling the cooling target S mounted on the slot 201.

The supply part 300 and the discharge part 400 may be connected to each other through a heat exchanger (not illustrated) separately installed outside the chamber 100. In this case, the cooling fluid C discharged from the chamber 100 through the discharge part 400 may be cooled while passing through the heat exchanger and then be supplied to the inside of the chamber 100 again through the supply part 300. Accordingly, the supply part 300 and the discharge part 400 may prevent an excessive increase of temperature of the cooling fluid C accommodated in the chamber 100.

The supply part 300 and the discharge part 400 may be disposed to be spaced apart from each other in an extending direction of the slot 201. For example, the supply part 300 and the discharge part 400 may be disposed at a lower side and an upper side, respectively, of the chamber 100. In this case, the cooling fluid C supplied from the lower side of the chamber 100 through the supply part 300 may flow to the upper side of the chamber 100 toward the discharge part 400 due to heat convection of the cooling fluid C itself that occurs as the temperature of the cooling fluid C increases in the process of heat exchange with the cooling target S. Accordingly, the supply part 300 and the discharge part 400 may decrease the power consumption of the pump that provides the driving force for a flow of the cooling fluid C. However, the supply part 300 and the discharge part 400 are not limited thereto and may be disposed at the upper side and the lower side, respectively, of the chamber 100.

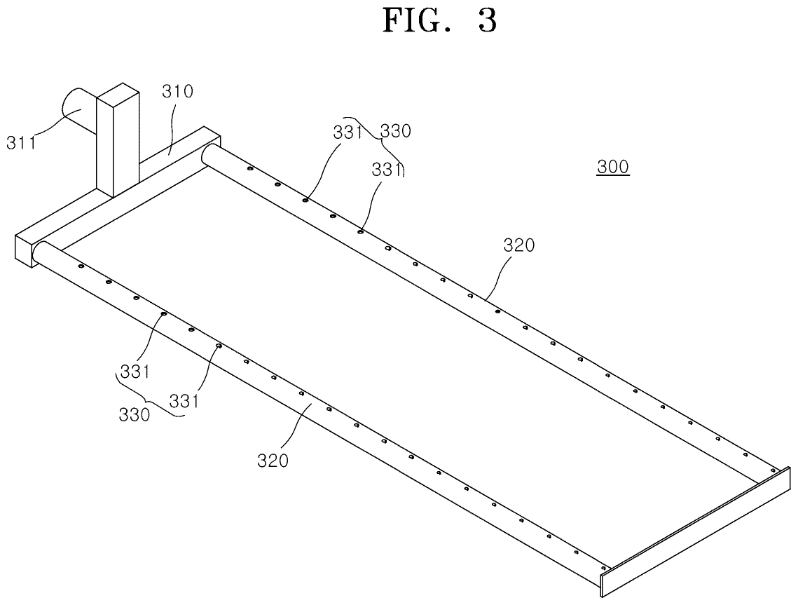

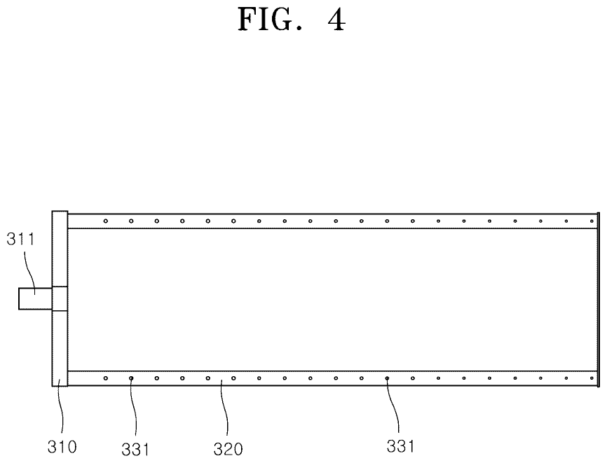

FIG. 3 is a perspective view schematically illustrating a configuration of a supply part according to one embodiment of the present invention, and FIG. 4 is a plan view schematically illustrating the configuration of the supply part according to one embodiment of the present invention.

Referring to FIGS. 1 to 4, the supply part 300 according to one embodiment of the present invention may include a supply body 310, a supply flow path portion 320, and a supply hole portion 330.

The supply body 310 may be fixed to the inside of the chamber 100 and may support the supply flow path portion 320 which will be described below. The supply body 310 may be formed to have the shape of a box that is hollow. The supply body 310 may be disposed at the lower side of the chamber 100 and may be fixed to an inner wall surface of the chamber 100. The supply body 310 may be integrally fixed to the chamber 100 by welding or the like or may be detachably coupled to the chamber 100 by bolting or the like.

An inlet 311 for transferring the cooling fluid C, which has passed through the external heat exchanger, to the inside of the supply body 310 may be formed in the supply body 310. For example, the inlet 311 may be formed to have the shape of a tube that is hollow and has both open sides. One side of the inlet 311 may be connected to the supply body 310 and may communicate with an inner space of the supply body 310. The other side of the inlet 311 may pass through the inner wall surface of the chamber 100 and protrude to the outside of the chamber 100. The other side of the inlet 311 may be connected to an outlet side of the heat exchanger installed outside the chamber 100 via a pipe, a hose, or the like.

The supply flow path portion 320 extends from the supply body 310 and is disposed to face one side of the slot 201. For example, the supply flow path portion 320 may be formed to have the shape of a tube that is hollow and has one open side. The one open side of the supply flow path portion 320 may be connected to the supply body 310 and may communicate with the inner space of the supply body 310.

The supply flow path portion 320 may have a longitudinal direction extending in a direction parallel to the first direction, that is, the X-axis direction (based on FIGS. 1 and 2). The supply flow path portion 320 may be disposed at a lower side of the rack module 200. The supply flow path portion 320 may have an upper surface disposed to be spaced a predetermined distance apart from and face lower surfaces of the plurality of slots 201 arranged in the first direction.

The supply flow path portion 320 may be formed as a plurality of supply flow path portions 320. The plurality of supply flow path portions 320 may be arranged in at least two or more rows in the second direction, that is, the Y-axis direction (based on FIGS. 1 and 2). The plurality of supply flow path portions 320 arranged in the second direction may be disposed parallel to each other.

The supply flow path portions 320 arranged in the second direction may be equal in number to the rows of the slots 201 arranged in the second direction. Each of the supply flow path portions 320 may be disposed to individually face a different row of the plurality of slots 201 arranged in the second direction. For example, the supply flow path portion 320 may be provided as a pair of supply flow path portions 320. The pair of supply flow path portions 320 may be arranged in two rows in the second direction. Each of the supply flow path portions 320 may be disposed to individually face a different row of slots 201 arranged in the second direction.

A busbar (not illustrated) that is electrically connected to the cooling target S mounted on the slot 210 may be installed between neighboring supply flow path portions 320.

The supply hole portion 330 is formed to pass through the supply flow path portion 320 and sprays the cooling fluid C toward one side of the slot 201.

The supply hole portion 330 may include a supply hole 331.

The supply hole 331 may vertically pass through an upper surface of the supply flow path portion 320 in the Z-axis direction (based on FIGS. 1 and 2) and may communicate with an inner space of the supply flow path portion 320. The supply hole 331 may be provided as a plurality of supply holes 331. The plurality of supply holes 331 may be disposed to be spaced apart from each other on the supply flow path portion 320.

The plurality of supply holes 331 may be arranged in at least two or more rows in the first direction on each supply flow path portion 320. The number of the plurality of supply holes 331 formed on any one supply flow path portion 320 may be equal to the number of rows of the plurality of slots 210 arranged in the first direction or may be larger than the number of rows of the plurality of slots 210 arranged in the first direction.

Each slot 210 may be disposed to face at least one or more supply holes 331. For example, the supply holes 331 may be arranged in twenty one rows in the first direction on each supply flow path portion 320. The pair of supply flow path portions 320 may be disposed to face the slots 210 arranged in two rows in the second direction, and the plurality of supply holes 331 arranged in twenty one rows in the first direction on each supply flow path portion 320 may be disposed to individually face different slots 210 arranged in twenty one rows in the first direction. Accordingly, each supply hole 331 may individually spray the cooling fluid C transferred from the supply body 310 to the supply flow path portion 320 toward a lower surface of each slot 201. However, the supply holes 331 are not limited thereto, and two or more supply holes 331 may be disposed to face each slots 210.

The plurality of supply holes 331 may be formed to have different diameters. A detailed configuration relating to the diameters of the plurality of supply holes 331 will be described below.

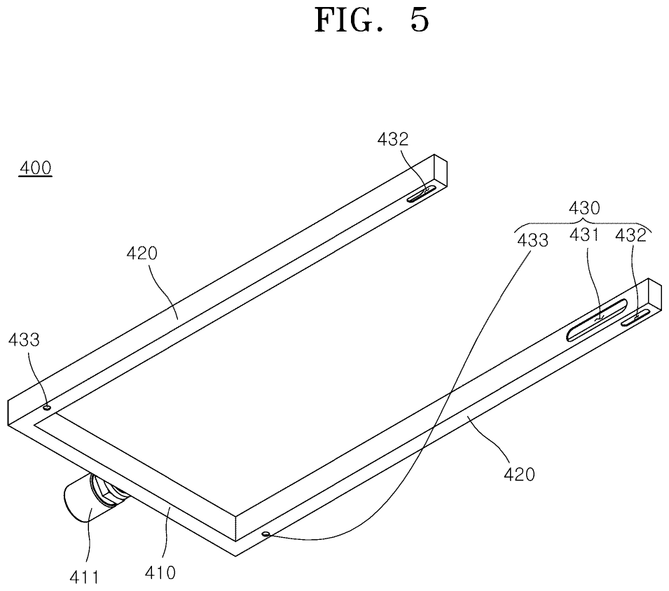

FIG. 5 is a perspective view schematically illustrating a configuration of a discharge part according to one embodiment of the present invention.

Referring to FIGS. 1 to 5, the discharge part 400 according to one embodiment of the present invention includes a discharge body 410, a discharge flow path portion 420, and a discharge hole portion 430.

The discharge body 410 is fixed to the inside of the chamber 100 and is disposed to be spaced apart from the supply body 310. For example, the discharge body 410 may be formed to have the shape of a box that is hollow. The discharge body 410 may be disposed at the upper side of the chamber 100 and may be fixed to the inner wall surface of the chamber 100. More specifically, the discharge body 410 may be disposed to vertically face the supply body 310 in the Z-axis direction (based on FIGS. 1 and 2) and may be fixed to the inner wall surface of the chamber 100 to which the supply body 310 is fixed. In this case, the discharge body 410 may be integrally fixed to the chamber 100 by welding or the like or may be detachably coupled to the chamber 100 by bolting or the like.

An outlet 411 for transferring the cooling fluid C discharged from the chamber 100 to the external heat exchanger may be formed in the discharge body 410. For example, the outlet 411 may be formed to have the shape of a tube that is hollow and has both open sides. One side of the outlet 411 may be connected to the discharge body 410 and may communicate with an inner space of the discharge body 410. The other side of the outlet 411 may pass through the inner wall surface of the chamber 100 and protrude to the outside of the chamber 100. The other side of the outlet 411 may be connected to an inlet side of the heat exchanger installed outside the chamber 100 via a pipe, a hose, or the like. The pump providing the driving force for a flow of the cooling fluid C may be connected between the inlet 311 and the heat exchanger or between the outlet 411 and the heat exchanger.

The discharge flow path portion 420 extends from the discharge body 410. For example, the discharge flow path portion 420 may be formed to have the shape of a tube that is hollow and has one open side. The one open side of the discharge flow path portion 420 may be connected to the discharge body 410 and may communicate with the inner space of the discharge body 410. The discharge flow path portion 420 may have a longitudinal direction extending in a direction parallel to the first direction, that is, the X-axis direction (based on FIGS. 1 and 2). The discharge flow path portion 420 may be formed as a pair of discharge flow path portions 420. The pair of discharge flow path portions 420 may be disposed to be parallel to each other in the Y-axis direction (based on FIGS. 1 and 2). Outer side surfaces of the pair of discharge flow path portions 420 may come in contact with an inner wall surface of the chamber 100 that is disposed to be perpendicular to the Y-axis direction (based on FIGS. 1 and 2). Accordingly, the discharge flow path portion 420 may open an upper surface of the slot 201 and guide the cooling target S to smoothly enter or exit through the upper surface of the slot 201. The pair of discharge flow path portions 420 may have inner side surfaces disposed to face both side surfaces of the rack module 200 that are disposed to be perpendicular to the Y-axis direction.

The discharge hole portion 430 is formed to pass through the discharge flow path portion 420 and suctions the cooling fluid C discharged from the other side of the slot 201. The discharge hole portion 430 may be individually formed for each of the pair of discharge flow path portions 420.

The discharge hole portion 430 may include a first discharge hole 431.

The first discharge hole 431 is formed to pass through one surface of the discharge flow path portion 420 and suctions the cooling fluid C that has passed through the slot 201 after being sprayed from the supply hole 331. For example, the first discharge hole 431 may be formed to have the shape of a hole that vertically passes through an inner side surface of the discharge flow path portion 420, which is disposed to face a side surface of the rack module 200, in the Y-axis direction and communicates with an inner space of the discharge flow path portion 420. The first discharge hole 431 may be formed to have the shape of a slot whose longitudinal direction extends in the longitudinal direction of the discharge flow path portion 420. The first discharge hole 431 may be disposed at a rear end of the discharge flow path portion 420 that is disposed at an opposite side of the discharge body 410.

The plurality of supply holes 331 may have a diameter that increases proportionally to a distance from the first discharge hole 431. In the present embodiment, a single first discharge hole 431 may be formed for each discharge flow path portion 420.

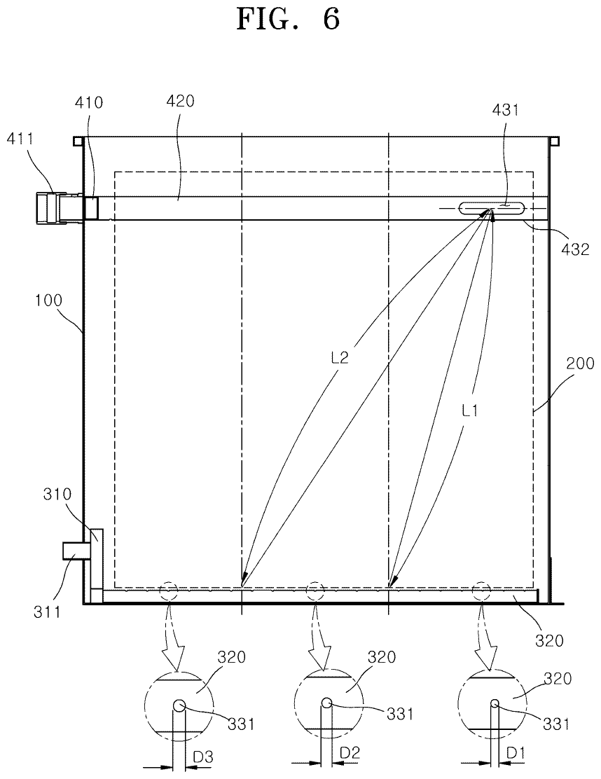

FIG. 6 is a view schematically illustrating a correlation between a diameter of a plurality of supply holes and a first discharge hole according to one embodiment of the present invention.

Referring to FIG. 6, among the plurality of supply holes 331, the supply hole 331 whose distance from the first discharge hole 431 is smaller than a first predetermined distance L1 may be formed to have a first diameter D1.

Also, among the plurality of supply holes 331, the supply hole 331 whose distance from the first discharge hole 431 is larger than the first predetermined distance L1 and smaller than a second predetermined distance L2 may be formed to have a second diameter D2 that is larger than the first diameter D1.

Also, among the plurality of supply holes 331, the supply hole 331 whose distance from the first discharge hole 431 is larger than the second predetermined distance L2 may be formed to have a third diameter D3 that is larger than the second diameter D2.

Here, the first predetermined distance L1 and the second predetermined distance L2 are distances from a central portion of the first discharge hole 431 to different arbitrary points on the upper surface of the supply flow path portion 320, and the second predetermined distance L2 may be changed to various values within a wider range than the first predetermined distance L1.

Also, the first diameter D1, the second diameter D2, and the third diameter D3 may be changed to various values within a range in which the sizes thereof sequentially increase. For example, the first diameter D1, the second diameter D2, and the third diameter D3 may be formed in a ratio of 4:5:6.

However, the diameters of the plurality of supply holes 331 are not limited thereto and may also individually increase proportionally to the distance from the first discharge hole 431.

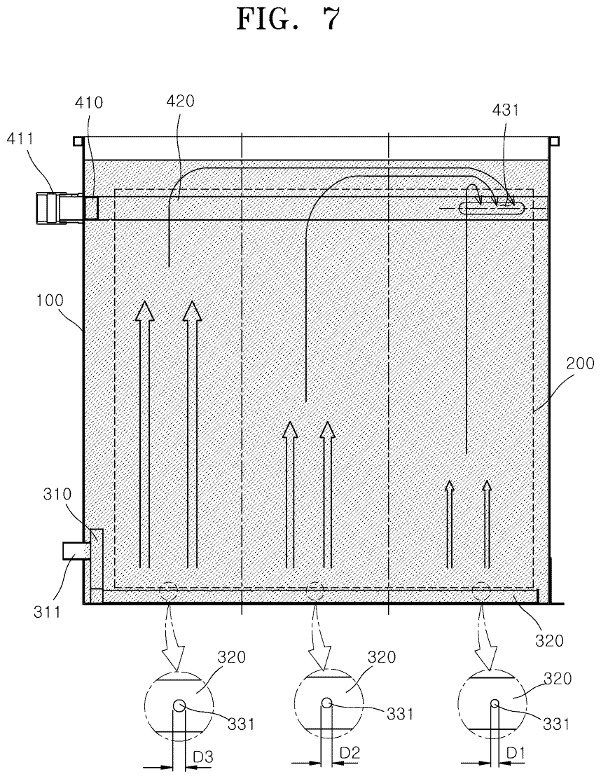

FIG. 7 is a view schematically illustrating operational states of the supply hole and the first discharge hole according to one embodiment of the present invention.

Referring to FIG. 7, since the first discharge hole 431 is disposed at the rear end of the discharge flow path portion 420, a suction force generated at the first discharge hole 431 acts with different sizes on the cooling fluid C sprayed from the plurality of supply holes 331.

That is, the size of the suction force acting on the cooling fluid C sprayed from the supply hole 331 located at a front end (a left side end based on FIG. 7) of the supply flow path portion 320 is smaller than the size of the suction force acting on the cooling fluid C sprayed from the supply hole 331 located at a rear end (a right side end based on FIG. 7) of the supply flow path portion 320.

In this case, unless a separate external force is applied to the cooling fluid C, the cooling fluid C sprayed from the supply hole 331 located at the front end of the supply flow path portion 320 passes through the slot 201 at a lower flow speed than the cooling fluid C sprayed from the supply hole 331 located at the rear end of the supply flow path portion 320 or stagnates in the slot 201, and efficiency of cooling the cooling target S mounted on the slot 201 disposed to face the supply hole 331 located at the front end of the supply flow path portion 320 relatively decreases.

Meanwhile, since the diameters of the plurality of supply holes 331 are formed to increase proportionally to the distance from the first discharge hole 431 as described above, the cooling fluid C sprayed from the supply hole 331 located at the front end of the supply flow path portion 320 may have a higher flow speed and a higher flow rate than the cooling fluid C sprayed from the supply hole 331 located at the rear end of the supply flow path portion 320.

That is, the size of a spraying force acting on the cooling fluid C sprayed from the supply hole 331 located at the front end of the supply flow path portion 320 is larger than the size of a spraying force acting on the cooling fluid C sprayed from the supply hole 331 located at the rear end of the supply flow path portion 320.

In this way, the difference in spraying forces acting on the cooling fluid C sprayed from the plurality of supply holes 331 acts as a force that offsets the difference in suction forces applied from the first discharge hole 431.

Accordingly, the cooling fluid C sprayed from each supply hole 331 may be suctioned to the first discharge hole 431 with a uniform flow rate and a uniform flow speed and may uniformly cool the plurality of cooling targets S regardless of the position of the slot 201.

The discharge hole portion 430 according to the present embodiment may further include a second discharge hole 432.

The second discharge hole 432 is formed to pass through the other surface of the discharge flow path portion 420 and prevents bubbles from being introduced into the discharge flow path portion 420.

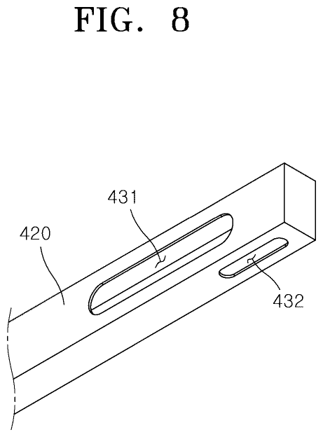

FIG. 8 is an enlarged view schematically illustrating a configuration of a second discharge hole according to one embodiment of the present invention.

Referring to FIGS. 2 and 8, the second discharge hole 432 may be formed to have the shape of a hole that vertically passes through a lower surface of the discharge flow path portion 420 in the Z-axis direction and communicates with the inner space of the discharge flow path portion 420. The second discharge hole 432 may be formed to have the shape of a slot whose longitudinal direction extends in the longitudinal direction of the discharge flow path portion 420. The second discharge hole 432 may be disposed at the rear end of the discharge flow path portion 420 that is disposed at the opposite side of the discharge body 410.

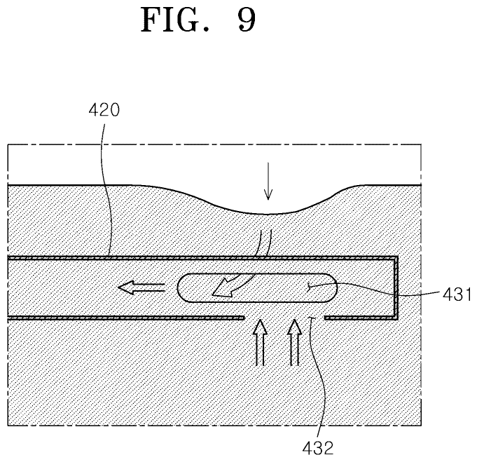

FIG. 9 is a view schematically illustrating an operational state of the second discharge hole according to one embodiment of the present invention.

Referring to FIG. 9, since the first discharge hole 431 is disposed at a side surface of the discharge flow path portion 420, the first discharge hole 431 suctions the cooling fluid C located at an upper side of the discharge flow path portion 420, and the level of the cooling fluid C located at an upper side of the first discharge hole 431 locally decreases.

When the level of the cooling fluid C is not sufficiently secured, the first discharge hole 431 may be partially exposed to the atmosphere or generate an eddy current in a process of suctioning the cooling fluid C, and thus bubbles may be introduced into the discharge flow path portion 420.

Since the second discharge hole 432 suctions the cooling fluid Cat a different position from the first discharge hole 431, the second discharge hole 432 may distribute the flow rate of the cooling fluid C suctioned to the first discharge hole 431.

Also, since the second discharge hole 432 is formed to pass through the lower surface of the discharge flow path portion 420, the second discharge hole 432 may decrease the flow rate of the cooling fluid C suctioned from the upper side of the first discharge hole 431.

Due to such an action, the second discharge hole 432 may mitigate a local decrease in the level of the cooling fluid C in some parts and may prevent bubbles from being introduced into the discharge flow path portion 420.

The discharge hole portion 430 according to the present embodiment may further include a third discharge hole 433.

The third discharge hole 433 is formed to pass through the discharge flow path portion 420 and prevents the cooling fluid C from stagnating in the chamber 100. Referring to FIG. 5, the third discharge hole 433 according to one embodiment of the present invention may be formed to have the shape of a hole that vertically passes through the lower surface of the discharge flow path portion 420 in the Z-axis direction and communicates with the inner space of the discharge flow path portion 420. The third discharge hole 433 may be disposed at a front end of the discharge flow path portion 420 that is disposed at the discharge body 410 side. That is, the first discharge hole 431 and the third discharge hole 433 may be disposed at both ends of the discharge flow path portion 420.

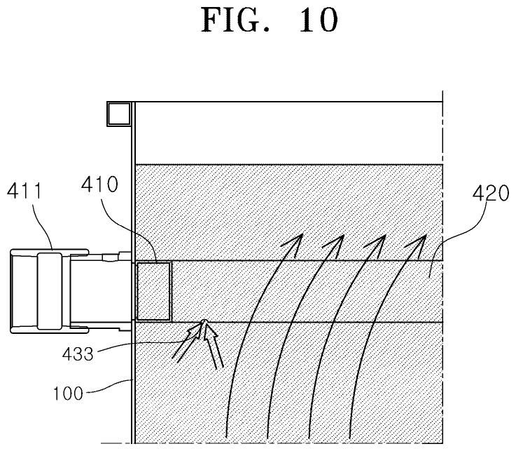

FIG. 10 is a view schematically illustrating an operational state of a third discharge hole according to one embodiment of the present invention.

Referring to FIG. 10, since the first discharge hole 431 is disposed at the rear end of the discharge flow path portion 420, the cooling fluid C supplied to the inside of the chamber 100 through the supply hole 331 flows in a form that converges toward the rear end of the discharge flow path portion 420.

Accordingly, at the front end side of the discharge flow path portion 420, a dead water zone in which the cooling fluid C is not smoothly suctioned into the first discharge hole 431 and stagnates is formed.

The third discharge hole 433 disposed at an opposite side of the first discharge hole 431 suctions the cooling fluid C located in the dead water zone into the discharge flow path portion 420, and in this way, the phenomenon of stagnation of the cooling fluid C in the chamber 100 can be relieved.

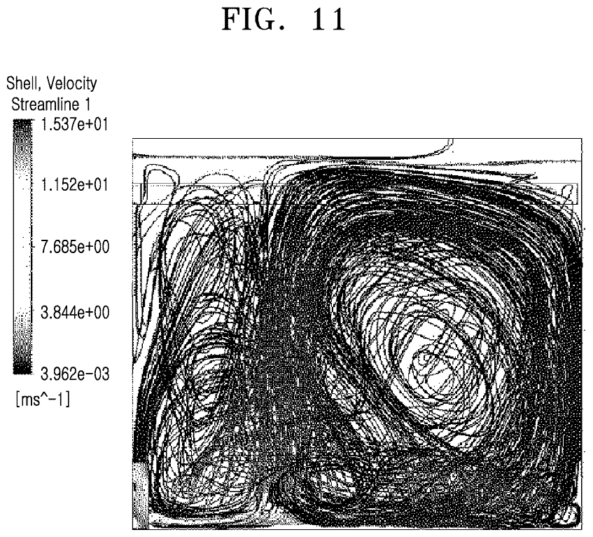

FIG. 11 is a view schematically illustrating an experimental result of the immersion cooling apparatus according to one embodiment of the present invention.

Referring to FIG. 11, as a result of conducting a flow analysis experiment by computational fluid dynamics (CFD) for the immersion cooling apparatus according to one embodiment of the present invention that has the above-described configuration, it was confirmed that the cooling fluid C supplied from the supply hole 331 was suctioned into the first discharge hole 431 and the second discharge hole 432 with a uniform flow speed across the entire region of the chamber 100.

Also, it was confirmed that, at the front end region of the discharge flow path portion 420 located at the opposite side of the first discharge hole 431, due to the third discharge hole 433, the cooling fluid C was smoothly suctioned into the discharge flow path portion 420 without stagnating.

Hereinafter, an immersion cooling apparatus according to another embodiment of the present invention will be described.

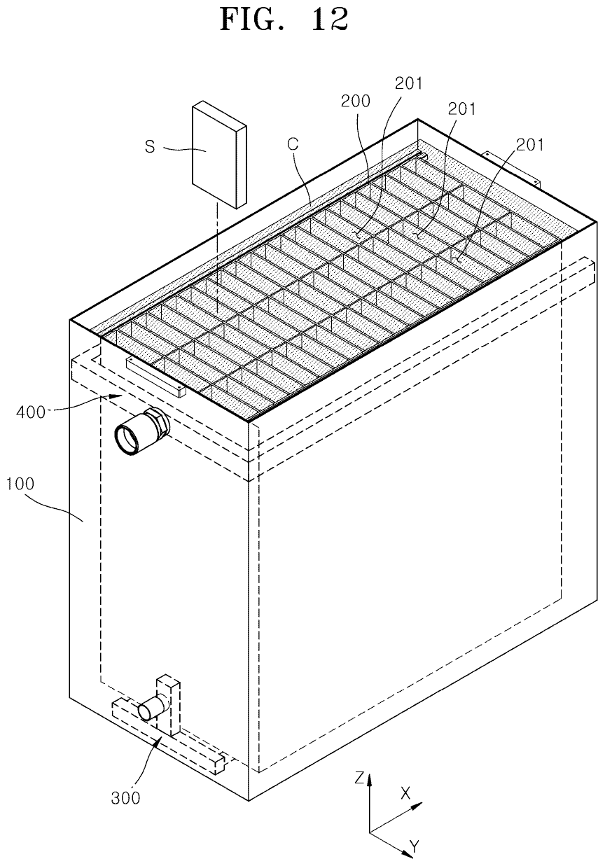

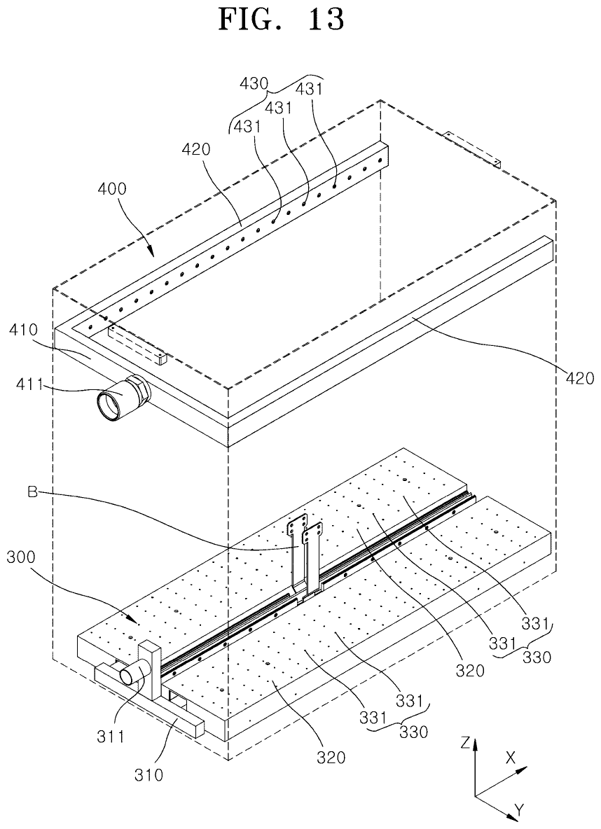

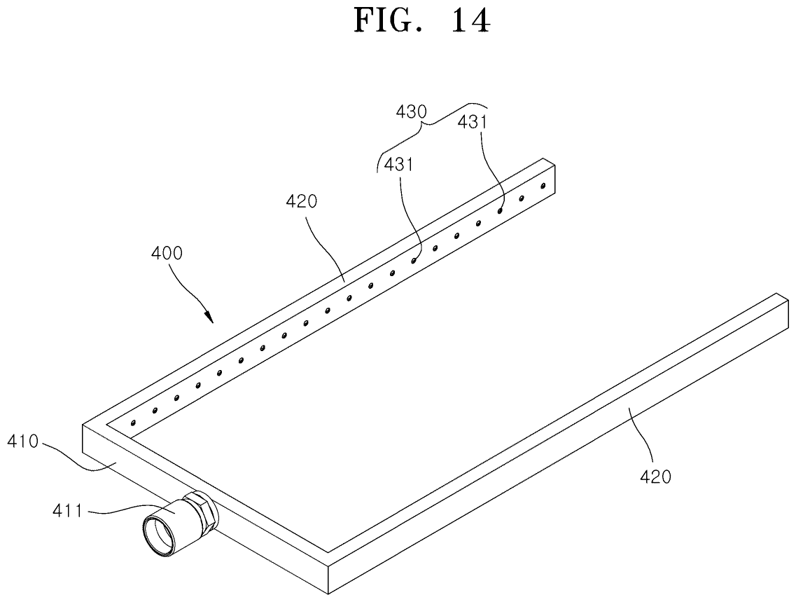

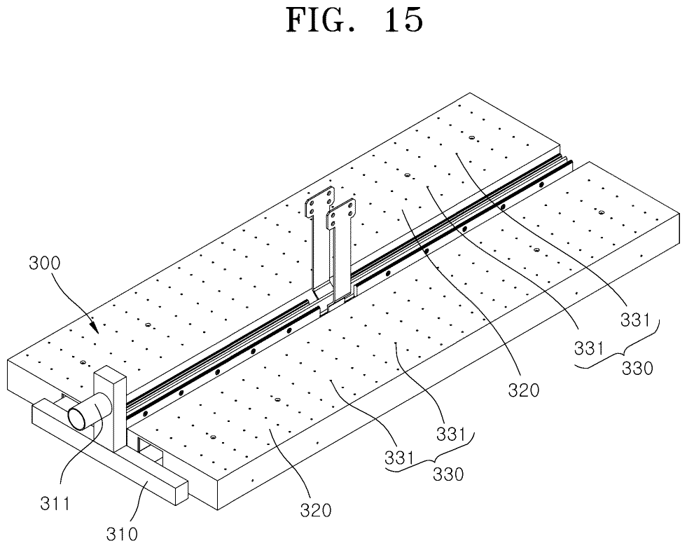

FIG. 12 is a perspective view schematically illustrating a configuration of an immersion cooling apparatus according to another embodiment of the present invention, FIG. 13 is a perspective view schematically illustrating the configuration of the immersion cooling apparatus excluding a rack module according to another embodiment of the present invention, FIG. 14 is a perspective view schematically illustrating a configuration of a supply part according to another embodiment of the present invention, and FIG. 15 is a perspective view schematically illustrating a configuration of a discharge part according to another embodiment of the present invention.

Referring to FIGS. 12 to 15, the immersion cooling apparatus according to the present embodiment may be configured to be the same as the immersion cooling apparatus according to one embodiment of the present invention that has been described above based on FIGS. 1 to 11, except for detailed configurations of the slots 210, the supply part 300, and the discharge part 400.

In the present embodiment, the number of the plurality of supply flow path portions 320 arranged in the second direction may be smaller than the number of rows of the plurality of slots 201 arranged in the second direction. For example, the plurality of slots 210 may be arranged in three rows in the second direction in the rack module 200. Also, the supply flow path portion 320 may be formed as a pair of supply flow path portions 320, and the pair of supply flow path portions 320 may be arranged in two rows in the second direction.

A width of the supply flow path portion 320 that is parallel to the second direction may be larger than a width of the slot 201 that is parallel to the second direction. Accordingly, each supply flow path portion 320 may be disposed to face at least two or more slots 201 in the second direction. For example, any one supply flow path portion 320 of the supply flow path portions 320 arranged in two rows in the second direction may be disposed to face, among the plurality of slots 210 arranged in three rows in the second direction, a slot 210 arranged in the first row and a half region of a slot 210 arranged in the second row. Also, the other supply flow path portion 320 of the supply flow path portions 320 arranged in two rows in the second direction may be disposed to face, among the plurality of slots 210 arranged in three rows in the second direction, a slot 210 arranged in the third row and the other half region of the slot 210 arranged in the second row.

The plurality of supply holes 331 may be arranged in at least two or more rows in the first direction and the second direction. The number of rows of the plurality of supply holes 331 arranged in the second direction may be larger than the number of rows of the plurality of slots 210 arranged in the second direction. For example, for each supply flow path portion 320, the plurality of supply holes 331 may be arranged in twenty one rows in the first direction. The plurality of supply holes 331 may be arranged in a total of twelve rows in the second direction and may be arranged in six rows in the second direction for each supply flow path portion 320.

The plurality of supply holes 331 may be formed to have the same diameter. For example, a diameter of each supply hole 331 may be 3 mm.

Each slots 210 may be disposed to face one supply hole 331 in the first direction and four supply holes 331 in the second direction.

In the present embodiment, the first discharge hole 431 may be provided as a plurality of first discharge holes 431. The plurality of first discharge holes 431 may be arranged in at least two or more rows in the first direction on the inner side surface of the discharge flow path portion 420. For example, the plurality of first discharge holes 431 may be arranged in twenty one rows in the first direction. Each of the first discharge holes 431 arranged in the first direction may be disposed to individually face a different row of slots 210 arranged in the first direction. Accordingly, the first discharge holes 431 may individually suction the cooling fluid C that has passed through each of the slots 210 arranged in the first direction and thus may promptly discharge the heat-exchanged cooling fluid C from the chamber 100.

The plurality of first discharge holes 431 may be formed to have the same diameter.

On the other hand, the plurality of first discharge holes 431 arranged in the first direction may be formed to have different diameters.

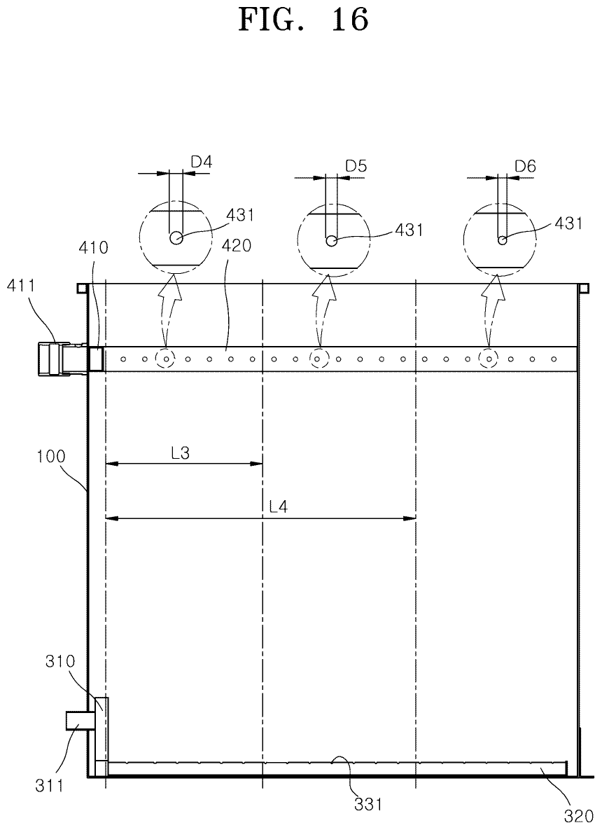

FIG. 16 is a view schematically illustrating a correlation between diameters of a plurality of first discharge holes according to another embodiment of the present invention.

Referring to FIG. 16, diameters of the plurality of first discharge holes 431 arranged in the first direction may increase proportionally to a distance from the discharge body 410. A flow speed of the cooling fluid C introduced into each first discharge hole 431 is inversely proportional to the distance from the discharge body 410. Therefore, when the diameters of the plurality of first discharge holes 431 increase proportionally to the distance from the discharge body 410, a flow rate of the cooling fluid C introduced into each first discharge hole 431 may be uniformly maintained.

The diameters of the plurality of first discharge holes 431 may increase in stages at every predetermined distance. For example, among the plurality of first discharge holes 431 arranged in the first direction, the first discharge hole 431 whose distance from the discharge body 410 is smaller than a first discharge distance L3 may be formed to have a first discharge diameter D4.

Also, among the plurality of first discharge holes 431, the first discharge hole 431 whose distance from the discharge body 410 is larger than the first discharge distance L3 and smaller than a second discharge distance LA may be formed to have a second discharge diameter D5 larger than the first discharge diameter D4.

Also, among the plurality of first discharge holes 431, the first discharge hole 431 whose distance from the discharge body 410 is larger than the second discharge distance L4 may be formed to have a third discharge diameter D6 larger than the second discharge diameter D5.

Here, the first discharge distance L3 and the second discharge distance LA are distances from the discharge body 410 to different arbitrary points that are spaced apart in the first direction and located between the pair of discharge flow path portions 420, and the second discharge distance L4 may be changed to various values within a wider range than the first discharge distance L3.

Also, the first discharge diameter D4, the second discharge diameter D5, and the third discharge diameter D6 may be changed to various values within a range in which the sizes thereof sequentially increase.

However, the diameters of the plurality of first discharge holes 431 are not limited thereto and may also individually increase proportionally to the distance from the discharge body 410.

A busbar B that is electrically connected to the cooling target S mounted on the slot 210 may be installed between neighboring supply flow path portions 320.

Only some embodiments of the present invention have been described above with reference to the accompanying drawings. The present invention is not limited to the embodiments, and of course, those of ordinary skill in the art to which the present invention pertains may make various modifications and changes within the technical spirit of the present invention and the scope equivalent to the claims below.

1. An immersion cooling apparatus comprising:
a chamber;
a rack module installed in the chamber and having a plurality of slots each having a cooling target mounted thereon;
a supply part connected to the chamber and configured to supply a cooling fluid to the inside of the chamber; and
a discharge part disposed to be spaced apart from the supply part and configured to discharge the cooling fluid from the chamber.

2. The immersion cooling apparatus of claim 1, wherein:
the slot has both sides passing through the rack module to communicate with an inner space of the chamber; and
the supply part and the discharge part are disposed to be spaced apart from each other in an extending direction of the slot for the cooling fluid to flow through the slot.

3. The immersion cooling apparatus of claim 2, wherein the supply part is disposed at a lower side of the chamber, and the discharge part is disposed at an upper side of the chamber.

4. The immersion cooling apparatus of claim 2, wherein:
the supply part comprises a supply body fixed to the inside of the chamber, a supply flow path portion extending from the supply body and disposed to face one side of the slot, and a supply hole portion formed to pass through the supply flow path portion and configured to spray the cooling fluid toward the one side of the slot; and
the discharge part includes a discharge body fixed to the inside of the chamber and disposed to be spaced apart from the supply body, a discharge flow path portion extending from the discharge body, and a first discharge hole formed to pass through one surface of the discharge flow path portion and configured to suction the cooling fluid discharged from the other side of the slot.

5. The immersion cooling apparatus of claim 4, wherein:
the plurality of slots are arranged in at least two or more rows in a first direction; and
the supply flow path portion and the discharge flow path portion extend in a direction parallel to the first direction.

6. The immersion cooling apparatus of claim 5, wherein the supply hole portion comprises a plurality of supply holes, and each of the slots is disposed to face at least one or more of the supply holes.

7. The immersion cooling apparatus of claim 6, wherein the plurality of supply holes are arranged in at least two or more rows in the first direction.

8. The immersion cooling apparatus of claim 6, wherein the plurality of supply holes have diameters that increase proportionally to a distance from the first discharge hole.

9. The immersion cooling apparatus of claim 8, wherein, among the plurality of supply holes, the supply hole whose distance from the first discharge hole is smaller than a first predetermined distance has a first diameter, and the supply hole whose distance from the first discharge hole is larger than the first predetermined distance has a second diameter.

10. The immersion cooling apparatus of claim 6, wherein:
the plurality of slots are arranged in at least two or more rows in a second direction perpendicular to the first direction; and
the plurality of supply holes are arranged in at least two or more rows in the second direction.

11. The immersion cooling apparatus of claim 6, wherein:
the plurality of slots are arranged in at least two or more rows in a second direction perpendicular to the first direction; and
the supply flow path portion is provided as a plurality of supply flow path portions that are arranged in at least two or more rows in the second direction.

12. The immersion cooling apparatus of claim 10, wherein each of the supply flow path portions is disposed to face a different row of the slots arranged in the second direction.

13. The immersion cooling apparatus of claim 5, wherein the first discharge hole is provided as a plurality of first discharge holes, and the plurality of first discharge holes are arranged in at least two or more rows in the first direction.

14. The immersion cooling apparatus of claim 13, wherein each of the first discharge holes arranged in the first direction is disposed to face a different row of the slots arranged in the first direction.

15. The immersion cooling apparatus of claim 13, wherein the plurality of first discharge holes have diameters that increase proportionally to a distance from the discharge body.

16. The immersion cooling apparatus of claim 4, wherein the discharge part further comprises a second discharge hole formed to pass through the other surface of the discharge flow path portion and configured to prevent bubbles from being introduced into the discharge flow path portion.

17. The immersion cooling apparatus of claim 16, wherein the first discharge hole is formed to pass through a side surface of the discharge flow path portion, and the second discharge hole is formed to pass through a lower surface of the discharge flow path portion.

18. The immersion cooling apparatus of claim 16, wherein the discharge part further includes a third discharge hole configured to prevent the cooling fluid from stagnating in the chamber.

19. The immersion cooling apparatus of claim 18, wherein the first discharge hole and the third discharge hole are disposed at both ends of the discharge flow path portion.
